(19) United States
(12) Patent Application Publication
(10) Pub. No.: US 2026/0118383 A1
(43) Pub. Date: Apr. 30, 2026

(54) PROBE MEMBER FOR INSPECTION, MANUFACTURING METHOD THEREOF

(71) Applicant: Jung Gyun BAEK, Daegu (KR)

(72) Inventor: Jung Gyun BAEK, Daegu (KR)

(21) Appl. No.: 18/715,897

(22) PCT Filed: Dec. 1, 2022
(86) PCT No.: PCT/KR2022/019375

§ 371 Date: Jun. 3, 2024

(30) Foreign Application Priority Data
Dec. 10, 2021 (KR) 10-2021-0176912
Dec. 1, 2022 (KR) 10-2022-0165694

(51) Int. Cl. G01R 1/073

(52) U.S. Cl. CPC G01R 1/07342

(57) ABSTRACT

An inspection probe member according to an embodiment of the present disclosure includes a body part having a column shape, and a plurality of contact protrusions have vertices and provided on the body part set in a column cross-section region, in which the contact protrusion includes a vertical portion formed to be perpendicular to a surface of the body part and connected to the vertex, and an inclined portion inclinedly connected to an upper end of the vertical portion on the surface of the body part and connected to the vertex.

### TECHNICAL FIELD

The present disclosure relates to an inspection probe member and a method of manufacturing the same, and more particularly, to an inspection probe member having a contact protrusion, and a method of manufacturing the same.

### BACKGROUND ART

After semiconductor devices are completely produced, electrical inspections are performed to identify whether the semiconductor device normally operates or identify the reliability of the semiconductor device. The electrical inspection uses a test socket and a test device including a pad.

The test socket serves to connect a terminal of the semiconductor device and the pad of the test device, and the test socket enables the terminal of the semiconductor device and the test device to exchange electrical signals.

To this end, as a contact means, a pogo pin is positioned in the test socket. The pogo pin includes a probe member and an elastic member, allows the semiconductor device and the test device to smoothly come into contact with each other, and mitigates a mechanical impact that may occur when the semiconductor device and the test device come into contact with each other. Therefore, the pogo pins are used for many test sockets.

A contact protrusion of the probe member has a quadrangular pyramidal shape having an isosceles triangular shape, and an angle of a vertex is 70 to 90 degrees. Because the contact protrusion is relatively deeply inserted into an inspection object and facilitates an electrical flow, there is a need to precisely perform an electrical inspection.

### DISCLOSURE

### Technical Problem

The present disclosure attempts to provide an inspection probe member in which an angle of a vertex of a contact protrusion is minimized, such that the contact protrusion is relatively deeply inserted into an inspection object.

The present disclosure also attempts to provide a method of manufacturing the inspection probe member.

### Technical Solution

An embodiment of the present disclosure provides a method of manufacturing an inspection probe member, which manufactures an inspection probe member having a plurality of contact protrusions provided on a body part, the method including: a first step of forming a plurality of pyramidal grooves, which each at least has a symmetric structure in one direction, in a region corresponding to the body part of a substrate based on a direction perpendicular to a surface of the substrate; a second step of filling the pyramidal groove with a photoresist and coating the surface of the substrate with the photoresist as a first layer; a third step of patterning the first layer in a first pattern so as to correspond to the contact protrusion and the body part; a fourth step of filling a space of the pyramidal groove, which corresponds to the contact protrusion, with a photoresist and coating the first pattern with the photoresist as a second layer; a fifth step of patterning the second layer in a second pattern so as to correspond to the contact protrusion and the body part; a sixth step of forming the contact protrusion and the body part by plating an internal space, which is set by the pyramidal groove, the first pattern, and the second pattern, with metal; and a seventh step of acquiring the inspection probe member by removing the first pattern, the second pattern, and the substrate.

In the third step, a part of a first angle θ1 of the pyramidal groove may be opened by the first pattern, and a second angle θ2 of a vertex of the contact protrusion to be manufactured may be a part of the first angle (θ2=(part*θ1).

In the third step, the first pattern may define an inner vertical portion, and the pyramidal groove may define an outer inclined portion, such that the vertex may be formed.

In the fifth step, the first pattern may be opened by the second pattern, and the plurality of contact protrusions having the vertices may be formed on the body part to be manufactured.

In the fifth step, a height difference H may be formed between a surface of the first pattern at an inner upper end of the pyramidal groove and a surface of the substrate at an outer upper end of the pyramidal groove by the first pattern.

In the sixth step, the height difference H may be formed between a surface of the body part vertically connected to an inner side of the vertex of the contact protrusion and a surface of the body part inclinedly connected to an outer side of the contact protrusion vertex by the first pattern.

The sixth step may include: a sixth-first step of forming a first metal layer by plating an inner surface of the internal space, which is set by the pyramidal groove, the first pattern, and the second pattern, with first metal; and a sixth-second step of completing the contact protrusion and the body part as a second metal layer by plating the first metal layer with second metal.

In the seventh step, the inspection probe member, in which the contact protrusion and the body part have the first metal layer and the second metal layer, may be acquired by removing the first pattern, the second pattern, and the substrate.

In the third step, the first pattern may define an outer vertical portion, and the pyramidal groove may define an inner inclined portion, such that the vertex may be formed.

In the fifth step, the first pattern may be opened by the second pattern, and the plurality of contact protrusions having the vertices may be formed on the body part to be manufactured.

In the fifth step, a height difference H2 may be formed between a surface of the first pattern at an outer upper end of the pyramidal groove and a surface of the substrate at an inner upper end of the pyramidal groove by the first pattern.

In the sixth step, a height difference H may be formed between a surface of the body part inclinedly connected to an inner side of the contact protrusion vertex and a surface of the body part vertically connected to an outer side of the contact protrusion vertex by the first pattern.

Another embodiment of the present disclosure provides an inspection probe member including: a body part having a column shape; and a plurality of contact protrusions have vertices and provided on the body part set in a column cross-section region, in which the contact protrusion includes: a vertical portion formed to be perpendicular to a surface of the body part and connected to the vertex; and an inclined portion inclinedly connected to an upper end of the vertical portion on the surface of the body part and connected to the vertex.

The body part may be formed in a cylindrical shape, and the contact protrusion may have the vertical portion provided at a center side in a circular region, and the inclined portion provided outside the vertical portion in the circular region.

The contact protrusion may have an arc fan shape in a plan view, the vertical portion may be formed as an inner edge of an arc column, the inclined portions may be formed as two inclined surfaces formed outside two opposite sides based on a center cutting line of the arc column, and the vertex may be formed at an upper end intersection point between the inner edge and the two inclined surfaces.

The contact protrusion may have an isosceles triangular shape in a plan view in which a central angle is positioned outward, the vertical portion may be formed as an inner side surface of a triangular column, the inclined portions may be formed as two inclined surfaces formed outside two opposite sides based on a center cutting line of the triangular column, and the vertex may be formed at an upper end intersection point between the inner side surface and the two inclined surfaces.

The contact protrusion may have a quadrangular shape in a plan view, the vertical portion may be formed as an inner edge of a quadrangular column, the inclined portions may be formed as two inclined surfaces formed outside two opposite sides based on a diagonal center cutting line of the quadrangular column, and the vertex may be formed at an upper end intersection point between the inner edge and the two inclined surfaces.

The contact protrusion may have a circular or elliptical shape in a plan view, the vertical portion may be formed as an inner curved surface of a circular or elliptical column, the inclined portions may be formed as two inclined surfaces formed outside two opposite sides based on a center cutting line of a circle or ellipse, and the vertex may be formed at an upper end intersection point between the inner curved surface and the two inclined surfaces.

The contact protrusion may have a triangular shape in a plan view, the vertical portion may be formed as an inner edge of a triangular column, the inclined portion may be formed as a single inclined surface formed outward based on a center cutting line of a triangle, and the vertex may be formed at an upper end intersection point between the inner edge and the single inclined surface.

The contact protrusion may have a circular or elliptical shape in a plan view, the vertical portion may be formed as an inner curved surface of a circular or elliptical column, the inclined portion may be formed as a single inclined surface formed outward based on a center cutting line of a circle or ellipse, and the vertex may be formed at an upper end intersection point between the inner curved surface and the single inclined surface.

The body part may be formed in a cylindrical shape, and the contact protrusion may have the vertical portion provided outside a circular region, and the inclined portion provided inside the vertical portion in the circular region.

The contact protrusion may have an arc fan shape in a plan view, the vertical portion may be formed as an outer edge of an arc column, the inclined portions may be formed as two inclined surfaces formed inside two opposite sides based on a center cutting line of the arc column, and the vertex may be formed at an upper end intersection point between the outer edge and the two inclined surfaces.

The contact protrusion may have a triangular shape in a plan view in which a central angle is positioned inward, the vertical portion may be formed as an outer side surface of a triangular column, the inclined portions may be formed as two inclined surfaces formed inside two opposite sides based on a center cutting line of the triangular column, and the vertex may be formed at an upper end intersection point between the outer side surface and the two inclined surfaces.

The contact protrusion may have a quadrangular shape in a plan view, the vertical portion may be formed as an outer edge of a quadrangular column, the inclined portions may be formed as two inclined surfaces formed inside two opposite sides based on a diagonal center cutting line of the quadrangular column, and the vertex may be formed at an upper end intersection point between the outer edge and the two inclined surfaces.

The contact protrusion may have a circular or elliptical shape in a plan view, the vertical portion may be formed as an outer curved surface of a circular or elliptical column, the inclined portions may be formed as two inclined surfaces formed inside two opposite sides based on a center cutting line of a circle or ellipse, and the vertex may be formed at an upper end intersection point between the outer curved surface and the two inclined surfaces.

The contact protrusion may be a triangular shape in a plan view in which a central angle is positioned outward, the vertical portion may be formed as an outer edge of a triangular column, the inclined portion may be formed as a single inclined surface formed inward based on a center cutting line of the triangular column, and the vertex may be formed at an upper end intersection point between the outer edge and the single inclined surface.

The body part may further include an extension body divided into grooves so as to correspond to the plurality of contact protrusions, and the contact protrusion may further include an extension protrusion extending perpendicularly to the extension body from a lowermost end of the inclined portion.

### Advantageous Effect

According to the embodiment, the angle of the vertex of the contact protrusion may be minimized, such that the contact protrusion may be relatively deeply inserted into the inspection object. Therefore, according to the embodiment, the electrical flow is made smooth by the contact protrusion, which enables a precise electrical inspection.

### DESCRIPTION OF THE DRAWINGS

FIG. 1 is a flowchart illustrating cross-sections for explaining a method of manufacturing an inspection probe member according to a first embodiment of the present disclosure.

FIG. 2 is a flowchart illustrating cross-sections for explaining a method of manufacturing an inspection probe member according to a second embodiment of the present disclosure.

FIG. 3 is a flowchart illustrating cross-sections for explaining a method of manufacturing an inspection probe member according to a third embodiment of the present disclosure.

FIGS. 4A and 4B are a top plan view and a cross-sectional view of an inspection probe member according to a first embodiment of the present disclosure manufactured by a control method according to the first embodiment.

FIGS. 5A and 5B are a top plan view and a cross-sectional view of an inspection probe member according to a second embodiment of the present disclosure manufactured by the control method according to the first embodiment.

FIGS. 6A and 6B are a top plan view and a cross-sectional view of an inspection probe member according to a third embodiment of the present disclosure manufactured by the control method according to the first embodiment.

FIGS. 7A, 7B, and 7C are a top plan view, a cross-sectional view, and a perspective view of an inspection probe member according to a fourth embodiment of the present disclosure manufactured by the control method according to the first embodiment.

FIGS. 8A, 8B, and 8C are a top plan view, a cross-sectional view, and a perspective view of an inspection probe member according to a fifth embodiment of the present disclosure manufactured by the control method according to the first embodiment.

FIGS. 9A, 9B, and 9C are a top plan view, a cross-sectional view, and a perspective view of an inspection probe member according to a sixth embodiment of the present disclosure manufactured by the control method according to the first embodiment.

FIGS. 10A and 10B are a top plan view and a cross-sectional view of an inspection probe member according to a seventh embodiment of the present disclosure manufactured by a control method according to the second embodiment.

FIGS. 11A and 11B are a top plan view and a cross-sectional view of an inspection probe member according to an eighth embodiment of the present disclosure manufactured by the control method according to the second embodiment.

FIGS. 12A and 12B are a top plan view and a cross-sectional view of an inspection probe member according to a ninth embodiment of the present disclosure manufactured by the control method according to the second embodiment.

FIGS. 13A, 13B, and 13C are a top plan view, a cross-sectional view, and a perspective view of an inspection probe member according to a tenth embodiment of the present disclosure manufactured by the control method according to the second embodiment.

FIGS. 14A and 14B are a top plan view and a cross-sectional view of an inspection probe member according to an eleventh embodiment of the present disclosure manufactured by the control method of the second embodiment.

FIG. 15 is a perspective view of an inspection probe member according to a twelfth embodiment of the present disclosure manufactured by the control method according to the second embodiment.

### MODE FOR INVENTION

Hereinafter, embodiments of the present disclosure will be described in detail with reference to the accompanying drawings so that those with ordinary skill in the art to which the present disclosure pertains may easily carry out the embodiments. However, the present disclosure may be implemented in various different ways and is not limited to the embodiments described herein. In the drawings, a part irrelevant to the description will be omitted to clearly describe the present disclosure, and the same or similar constituent elements will be designated by the same reference numerals throughout the specification.

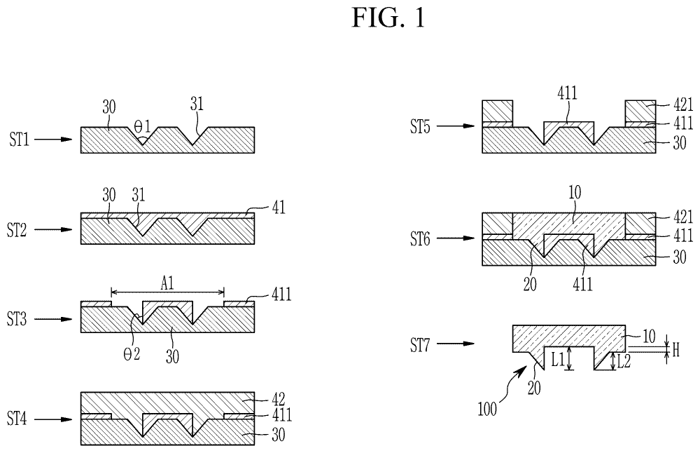

FIG. 1 is a flowchart illustrating cross-sections for explaining a method of manufacturing an inspection probe member according to a first embodiment of the present disclosure. For convenience, an inspection probe member 100 of the first embodiment will be described, focusing on a part of a body part 10 and a contact protrusion 20. The body part 10 may be variously formed and used for an inspection device.

With reference to FIG. 1, the method of manufacturing an inspection probe member according to the first embodiment includes a first step ST1, a second step ST2, a third step ST3, a fourth step ST4, a fifth step ST5, a sixth step ST6, and a seventh step ST7.

In the first step ST1, a plurality of pyramidal grooves 31 each having a symmetric structure (vertically symmetric in the drawings) or an asymmetric structure is formed in a substrate 30 in at least one direction based on a direction perpendicular to a surface of the substrate 30. The pyramidal groove 31 may be formed in various pyramidal shapes of various figures and have a symmetric or asymmetric structure. The pyramidal grooves 31 are formed in region A1 corresponding to the body part 10 of the inspection probe member 100.

For example, the substrate 30 may be formed as a single-crystal silicon wafer. The pyramidal groove 31 may be formed by applying a publicly-known technology such as an etching process to a single-crystal silicon wafer. That is, the pyramidal groove 31 defines a primary mold used to form a part of the contact protrusion 20 of the inspection probe member 100.

In the second step ST2, the pyramidal groove 31 is filled with a liquid photoresist, and a surface of the substrate 30 is coated with the photoresist as a first layer 41.

In the third step ST3, the first layer 41 is patterned in a first pattern 411 so as to correspond to the contact protrusion 20 and the body part 10. In this case, the contact protrusion 20 is formed to have a partial size of an angle of the pyramidal groove 31 or have an angle of ½ of the angle of the pyramidal groove 31. That is, an angle of a vertex of the contact protrusion 20 is set to a partial size of the angle of the pyramidal groove 31 or to an angle of ½ of the angle of the pyramidal groove 31. For example, the angle of the pyramidal groove 31 is 45 to 90 degrees while having a vertically symmetric structure, and the angle of the vertex is set to 25 to 45 degrees while having a vertically asymmetric structure. The case in which the contact protrusion has a partial size of the angle of the pyramidal groove may be more effective in comparison with a case in which the angle of the pyramidal groove 31 has an asymmetric structure. Hereinafter, for convenience, an example will be described in which the contact protrusion 20 has an angle of ½ of the angle of the pyramidal groove 31.

In the third step ST3, the exposure and development (ED) are performed on the first layer 41 formed by the photoresist, such that the first pattern 411 is formed. The first pattern 411 further defines a secondary mold on the primary mold formed as a part of the pyramidal groove 31.

In the third step ST3, an outer part or ½ of a first angle θ1 of the pyramidal groove 31 is opened by the first pattern 411, such that a second angle θ2 of the vertex of the contact protrusion 20 to be manufactured is an outer part or ½ of the first angle θ1 (θ2=(½ or part)*θ1). In the third step ST3, the first pattern 411 defines an inner vertical portion, and the pyramidal groove 31 defines an outer inclined portion, such that the vertex is formed. That is, the pyramidal groove 31 has a vertically asymmetric structure.

In the fourth step ST4, a space of the pyramidal groove 31, which corresponds to the contact protrusion 20, is filled with a liquid photoresist, and the photoresist is applied onto the first pattern 411 as a second layer 42.

In the fifth step ST5, the second layer 42 is patterned in a second pattern 421 so as to correspond to the contact protrusion 20 and the body part 10. A part or ½ of the pyramidal groove 31 is formed. That is, an angle of a vertex of the contact protrusion 20 is set to a partial size of the angle of the pyramidal groove 31 or to an angle of ½ of the angle of the pyramidal groove 31.

In the fifth step ST5, the exposure and development is performed on the second layer 42 formed by the photoresist in the space set by the first pattern 411 and the pyramidal groove 31, such that the second pattern 421 is formed. In this case, the first pattern 411 maintains the structure in an intact manner even during the process of performing the exposure and development on the second layer 42. In the second pattern 421, a tertiary mold is further formed on the secondary mold formed by a part of the pyramidal groove 31 and the second pattern 421. That is, the second pattern 421 is completed by restoring the first pattern 411 and further forming the tertiary mold.

In the fifth step ST5, the first pattern 411 is opened by the second pattern 421, such that the plurality of contact protrusions 20 each having the vertex is positioned on the body part 10 to be manufactured. In the fifth step ST5, a height difference H (see ST7) is formed between a surface of the first pattern 411 at an inner upper end of the pyramidal groove 31 and a surface of the substrate 30 at an outer upper end of the pyramidal groove 31 by the first pattern 411.

In the sixth step ST6, an internal space, which is set by a part of the pyramidal groove 31, the first pattern 411, and the second pattern 421, is plated with metal, such that the contact protrusion 20 and the body part 10 are formed. In this case, the contact protrusion 20 and the body part 10 are integrated by single plating, and no boundary line is formed between the contact protrusion 20 and the body part 10, such that high integrity is formed therebetween.

The contact protrusion 20 has a smaller angle than the pyramidal groove 31 formed by etching the substrate 30. The contact protrusion 20 formed in the sixth step ST6 is a portion that comes into contact with a surface of an inspection object that is an inspection target. The contact protrusion 20 may be formed more sharply.

In the sixth step ST6, the height difference H is formed between the surface of the body part 10 vertically connected to an inner side of the vertex of the contact protrusion 20 and the surface of the body part 10 inclinedly connected to an outer side of the vertex of the contact protrusion 20 by the first pattern 411.

In the seventh step ST7, the inspection probe member 100 is acquired by removing the first pattern 411, the second pattern 421, and the substrate 30. The height difference H, by which the contact protrusion 20 is connected to the body part 10, allows a vertical distance L1 between the vertex and the body part 10 at a vertical portion side to be longer than a vertical distance L2 between the vertex and the body part 10 at an outer inclined portion side (L1>L2). Therefore, when the contact protrusion 20 comes into contact with and is inserted into the inspection target, the inspection target may be prevented from being caught by the vertical portion side, and an insertion depth may be set on the basis of resistance made by the inclined portion.

The inspection probe member 100 of the first embodiment may be mounted in a barrel of a pogo pin (not illustrated) with an elastic member interposed therebetween. The inspection probe member 100 may be variously applied to devices required to come into contact with the inspection target to inspect the inspection target.

Hereinafter, various exemplary embodiments of the present invention will be described. A description of the components identical to the components described with reference to the first embodiment and the above-mentioned embodiments will be omitted, and the components different from the components described with reference to the first embodiment and the above-mentioned embodiments will be described.

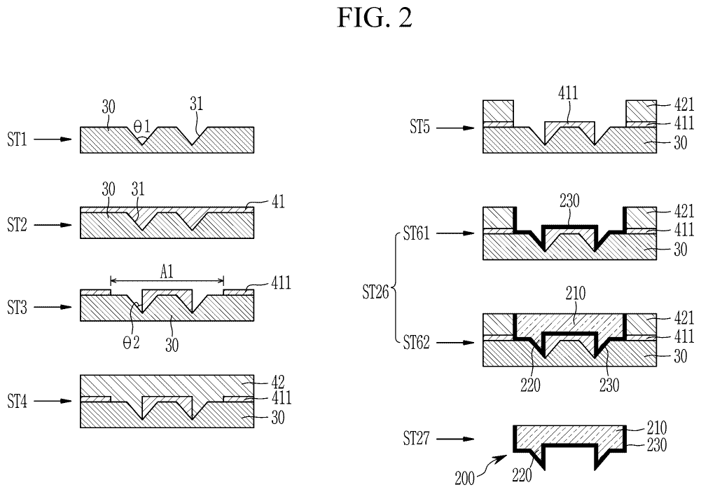

FIG. 2 is a flowchart illustrating cross-sections for explaining a method of manufacturing an inspection probe member according to a second embodiment of the present disclosure. With reference to FIG. 2, in the manufacturing method of the second embodiment, a sixth step ST26 includes a sixth-first step ST61 and a sixth-second step ST62.

In the sixth-first step ST61, a first metal layer 230 is formed by plating an inner surface of the internal space, which is set by the pyramidal groove 31, the first pattern 411, and the second pattern 421 with first metal. In sixth-second step ST62, a contact protrusion 220 and a body part 210 is completed by a second metal layer by plating the first metal layer 230 with second metal.

In the seventh step ST7, an inspection probe member 200, in which the contact protrusion 220 and the body part 210 have the first metal layer 230 and the second metal layer, is acquired by removing the first pattern 411, the second pattern 421, and the substrate 30.

Because the surfaces of the contact protrusion 220 and the body part 210 are plated with the first metal layer 230, the amount of use of the first metal is minimized, and a large amount of low-cost second metal is used, in case that the high-price, high-strength first metal is used. Therefore, the high-strength inspection probe member 200 may be obtained with low costs from the first metal layer 230.

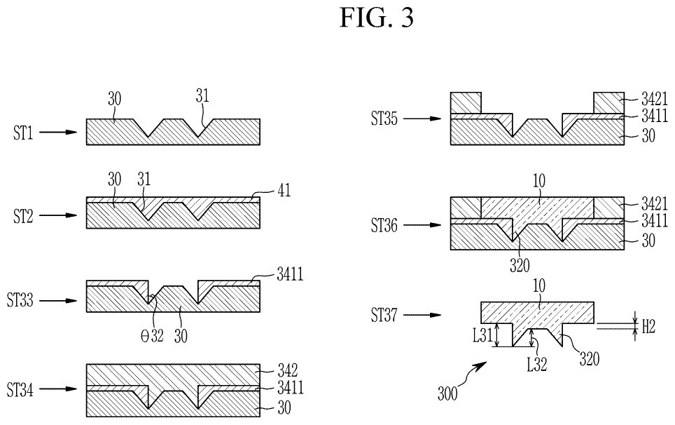

FIG. 3 is a flowchart illustrating cross-sections for explaining a method of manufacturing an inspection probe member according to a third embodiment of the present disclosure. With reference to FIG. 3, in the manufacturing method of the third embodiment, in the third step ST33, the first layer 41 is patterned in a first pattern 3411 so as to correspond to a contact protrusion 320 and the body part 10.

In the third step ST33, the exposure and development (ED) are performed on the first layer 41 formed by the photoresist, such that the first pattern 3411 is formed. The first pattern 3411 further defines a secondary mold on the primary mold formed as a part of the pyramidal groove 31.

In the third step ST33, an inner part of ½ of a first angle θ1 of the pyramidal groove 31 is opened by the first pattern 3411, such that a second angle θ32 of the vertex of the contact protrusion 320 to be manufactured is an inner part of ½ of the first angle θ1 (θ32=½*θ1). In the third step ST3, the first pattern 3411 defines an outer vertical portion, and the pyramidal groove 31 defines an inner inclined portion, such that the vertex is formed.

In the fourth step ST34, a space of the pyramidal groove 31, which corresponds to the contact protrusion 320, is filled with a liquid photoresist, and the photoresist is applied onto the first pattern 3411 as a second layer 342.

In the fifth step ST35, the first pattern 3411 is opened by the second pattern 3421, such that the plurality of contact protrusions 320 each having the vertex is positioned on the body part 310 to be manufactured. In the fifth step ST35, a height difference H2 (see ST37) is formed between a surface of the first pattern 3411 at an outer upper end of the pyramidal groove 31 and a surface of the substrate 30 at an inner upper end of the pyramidal groove 31 by the first pattern 3411.

In the sixth step ST36, an internal space, which is set by a part of the pyramidal groove 31, the first pattern 3411, and the second pattern 3421, is plated with metal, such that the contact protrusion 320 and the body part 10 are formed. In this case, the contact protrusion 320 and the body part 10 are formed by single plating, and no boundary line is formed between the contact protrusion 320 and the body part 10, such that high integrity is formed therebetween.

The contact protrusion 320 has a smaller angle than the pyramidal groove 31 formed by etching the substrate 30. The contact protrusion 320 formed in the sixth step ST36 is a portion that comes into contact with a surface of an inspection object that is an inspection target. The contact protrusion 320 may be formed more sharply.

In the sixth step ST36, the height difference H2 is formed between the surface of the body part 10 inclinedly connected to an inner side of the vertex of the contact protrusion 320 and the surface of the body part 10 vertically connected to an outer side of the vertex of the contact protrusion 320 by the first pattern 3411.

In the seventh step ST37, the inspection probe member 300 is acquired by removing the first pattern 3411, the second pattern 3421, and the substrate 30. The height difference H2, by which the contact protrusion 320 is connected to the body part 10, allows a vertical distance L31 between the vertex and the body part 10 at a vertical portion side to be longer than a vertical distance L32 between the vertex and the body part 10 at an outer inclined portion side (L31>L32). Therefore, when the contact protrusion 320 comes into contact with and is inserted into the inspection target, the inspection target may be prevented from being caught by the vertical portion side.

For convenience, the example has been described in which the method of manufacturing an inspection probe member of the second embodiment is applied to the first embodiment. However, the method of manufacturing an inspection probe member of the second embodiment may also be applied to the third embodiment correspondingly.

Hereinafter, inspection probe members of various embodiments of the present disclosure will be described. First, an inspection probe member manufactured by the manufacturing methods of the first and second embodiments will be described.

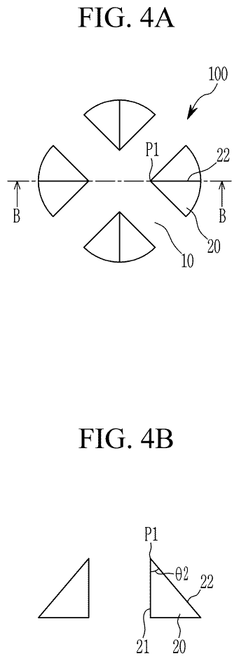

FIGS. 4A and 4B are a top plan view and a cross-sectional view of an inspection probe member according to a first embodiment of the present disclosure manufactured by a control method according to the first embodiment. FIGS. 4A and 4B are a top plan view and a cross-sectional view illustrating the arrangement and shape of the contact protrusion 20 in a state in which the inspection probe member 100 of FIG. 1 stands upright, the body part 10 is positioned at the lower side, and the contact protrusion 20 is positioned at the upper side.

The inspection probe member 100 includes the body part 10 having a column shape, and the plurality of contact protrusions 20 having vertices and provided on the body part 10 set as a planar region of a column. For convenience, for example, the body part 10 is formed in a cylindrical or polyprismatic shape (not illustrated). Therefore, the planar region of the cross-section of the column is set to a circular or polygonal region (not illustrated). Hereinafter, for convenience, the body part 10 will be described as being formed in a cylindrical shape.

The contact protrusion 20 includes a vertical portion 21 formed to be perpendicular to the surface of the body part 10 and connected to a vertex P1, and an inclined portion 22 inclinedly connected to an upper end of the vertical portion 21 on the surface of the body part 10 and connected to the vertex P1.

In the contact protrusion 20, the vertical portion 21 is provided at a center side of a circular region, and the inclined portion 22 is provided outside the vertical portion 21 in the circular region. In addition, the contact protrusion 20 has an arc or ¼-circular fan shape in a plan view, the vertical portion 21 is formed as an inner edge with an arc or ¼-cylindrical shape, the inclined portions 22 are formed as two inclined surfaces formed outside two opposite sides based on a center cutting line of the arc column or ¼-cylindrical shape, and the vertex P1 is formed at an upper end intersection point between the inner edge and the two inclined surfaces. The second angle θ2 of the vertex P1 of the contact protrusion 20 is formed outward and has a partial size of the first angle θ1 of the pyramidal groove 31 or has a size of ½ of the first angle θ1.

Therefore, when the contact protrusion 20 comes into contact with and is inserted into the inspection target, the inspection target is prevented from being caught by the vertical portion 21, and the insertion depth may be stably set by insertion resistance balanced by inclined portions 42 of the contact protrusions 20.

In accordance with the shapes of the vertex P1, the vertical portion 21, and the inclined portion 42, the vertex P1, the vertical portion 21, and the inclined portion 42 set strength in accordance with a planar area, the resistance, and the time from the contact with the inspection target to the completion of the insertion.

In accordance with various shapes, the contact protrusion having the vertex, the vertical portion, and the inclined portion variously set strength of the contact protrusion, the insertion resistance, and the time from the contact with the inspection target to the completion of the insertion.

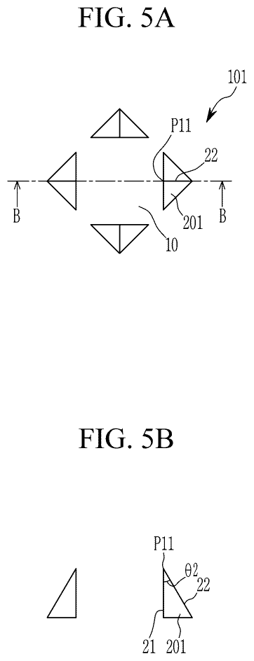

FIGS. 5A and 5B are a top plan view and a cross-sectional view of an inspection probe member according to a second embodiment of the present disclosure manufactured by the control method according to the first embodiment. With reference to FIGS. 5A and 5B, in an inspection probe member 101 of the second embodiment, the contact protrusion 201 has an isosceles triangular shape in a plan view in which a central angle is positioned outward, the vertical portion 21 is formed as an inner side surface of a triangular column, the inclined portions 22 are formed as two inclined surfaces formed outside two opposite sides based on a center cutting line of the triangular column, and a vertex P11 is formed at an upper end intersection point between the inner side surface and the two inclined surfaces. The second angle θ2 of the vertex P11 of the contact protrusion 201 is formed outward and has a size of ½ of the first angle θ1 of the pyramidal groove 31.

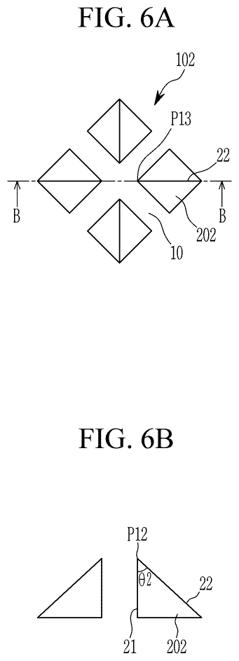

FIGS. 6A and 6B are a top plan view and a cross-sectional view of an inspection probe member according to a third embodiment of the present disclosure manufactured by the control method according to the first embodiment. With reference to FIGS. 6A and 6B, in an inspection probe member 102 of the third embodiment, the contact protrusion 202 has a quadrangular or square shape in a plan view, the vertical portion 21 is an inner edge of a quadrangular or square column, and the inclined portions 22 are formed as two inclined surfaces formed outside two opposite sides based on a diagonal center cutting line of the quadrangular or square column. A vertex P12 of the contact protrusion 202 is formed at an upper end intersection point between the inner edge and the two inclined surfaces.

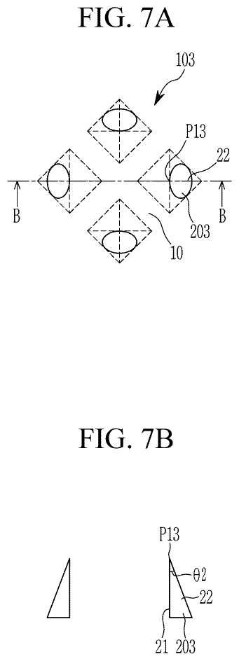

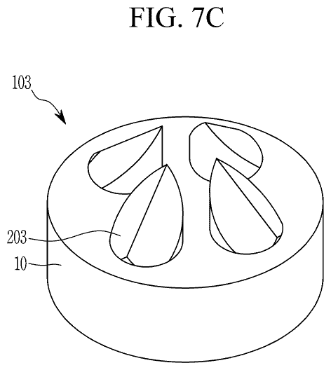

FIGS. 7A, 7B, and 7C are a top plan view, a cross-sectional view, and a perspective view of an inspection probe member according to a fourth embodiment of the present disclosure manufactured by the control method according to the first embodiment. With reference to FIGS. 7A, 7B, and 7C, in an inspection probe member 103 of the fourth embodiment, the contact protrusion 203 has a circular or elliptical shape in a plan view, the vertical portion 21 is formed as an inner curved surface of a circular or elliptical column, and the inclined portions 22 are formed as two inclined surfaces formed outside two opposite sides based on a center cutting line of a circle or ellipse. A vertex P13 of the contact protrusion 203 is formed at an upper end intersection point between the inner curved surface and the two inclined surfaces.

In the fourth embodiment, the contact protrusion 203 is formed so that the circular or elliptical column occupies only a part of an outer side of a planar quadrangular area of the contact protrusion 202 of the third embodiment. Therefore, the fourth embodiment may be applied to a smaller, preciser inspection target.

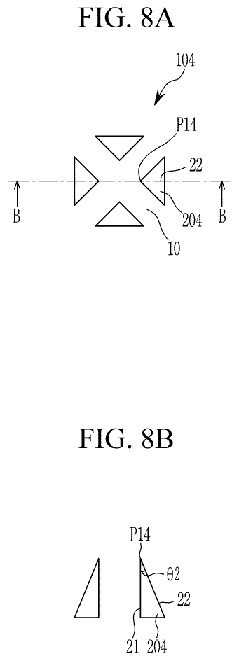

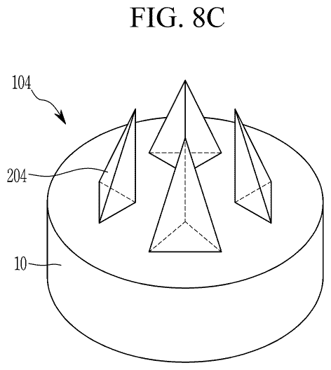

FIGS. 8A, 8B, and 8C are a top plan view, a cross-sectional view, and a perspective view of an inspection probe member according to a fifth embodiment of the present disclosure manufactured by the control method according to the first embodiment. With reference to FIGS. 8A, 8B, and 8C, in an inspection probe member 104 of the fifth embodiment, the contact protrusion 204 has a triangular or isosceles triangular shape in a plan view, the vertical portion 21 is formed as an inner edge of a triangular or isosceles triangular column, and the inclined portion 22 is formed as a single inclined surface formed outward based on a center cutting line of a triangle or isosceles triangle. A vertex P14 of the contact protrusion 204 is formed at an upper end intersection point between the inner edge and the single inclined surface.

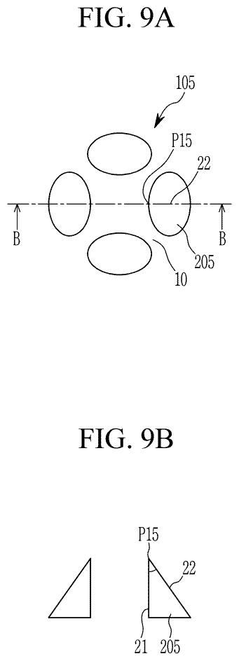

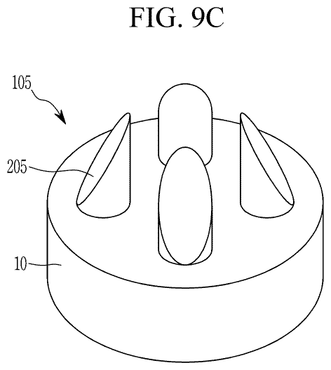

FIGS. 9A, 9B, and 9C are a top plan view, a cross-sectional view, and a perspective view of an inspection probe member according to a sixth embodiment of the present disclosure manufactured by the control method according to the first embodiment. With reference to FIGS. 9A, 9B, and 9C, in an inspection probe member 105 of the sixth embodiment, the contact protrusion 205 has a circular or elliptical shape in a plan view, the vertical portion 21 is formed as an inner curved surface of a circular or elliptical column, and the inclined portion 22 is formed as a single inclined surface formed outward based on a center cutting line of a circle or ellipse. A vertex P15 of the contact protrusion 205 is formed at an upper end intersection point between the inner curved surface and the single inclined surface.

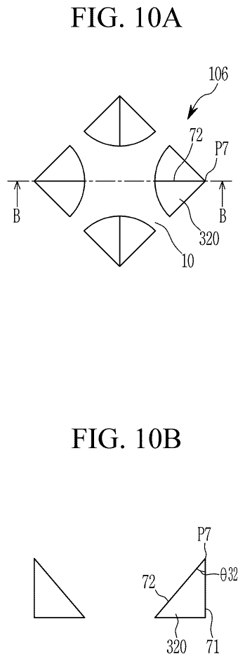

FIGS. 10A and 10B are a top plan view and a cross-sectional view of an inspection probe member according to a seventh embodiment of the present disclosure manufactured by a control method according to the second embodiment. With reference to FIGS. 10A and 10B, in an inspection probe member 106 of the seventh embodiment, the contact protrusion 320 has a vertical portion 71 provided outside a column cross-section region (e.g., a circular region), and an inclined portion 72 provided inside the vertical portion 71 in the column cross-section region. In addition, the contact protrusion 320 has an arc (e.g., ¼-circular) fan shape of a column cross-section in a plan view, the vertical portion 71 is formed as an outer edge of an arc column (e.g., ¼-cylindrical shape), and the inclined portions 72 are formed as two inclined surfaces formed inside two opposite sides based on a center cutting line of the arc column. A vertex P7 of the contact protrusion 320 is formed at an upper end intersection point between the outer edge and the two inclined surfaces. A second angle θ32 of the vertex P7 of the contact protrusion 320 is formed inward and has a size of ½ of the first angle θ1 of the pyramidal groove 31 or a partial size of the first angle θ1 of the pyramidal groove 31.

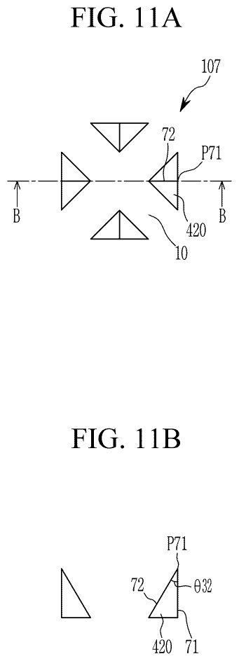

FIGS. 11A and 11B are a top plan view and a cross-sectional view of an inspection probe member according to an eighth embodiment of the present disclosure manufactured by the control method according to the second embodiment. With reference to FIGS. 11A and 11B, in an inspection probe member 107 of the eighth embodiment, a contact protrusion 420 has a triangular or isosceles triangular shape in a plan view in which a central angle is positioned inward, the vertical portion 71 is formed as an outer side surface of a triangular column, and the inclined portions 72 are formed as two inclined surfaces formed inside two opposite sides based on a center cutting line of the triangular column. A vertex P71 of the contact protrusion 420 is formed at an upper end intersection point between the outer side surface and the two inclined surfaces.

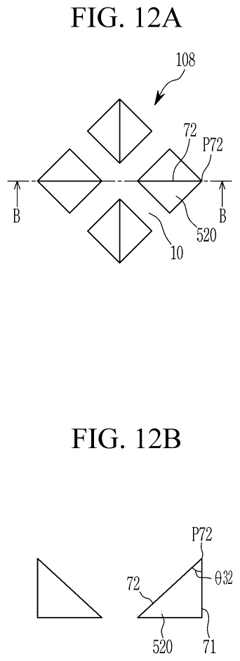

FIGS. 12A and 12B are a top plan view and a cross-sectional view of an inspection probe member according to a ninth embodiment of the present disclosure manufactured by the control method according to the second embodiment. With reference to FIGS. 12A and 12B, in an inspection probe member 108 of the ninth embodiment, a contact protrusion 520 has a quadrangular or square shape in a plan view, the vertical portion 71 is an outer edge of a quadrangular or square column, and the inclined portions 72 are formed as two inclined surfaces formed inside two opposite sides based on a diagonal center cutting line of the quadrangular or square column. A vertex P72 of the contact protrusion 520 is formed at an upper end intersection point between the outer edge and the two inclined surfaces.

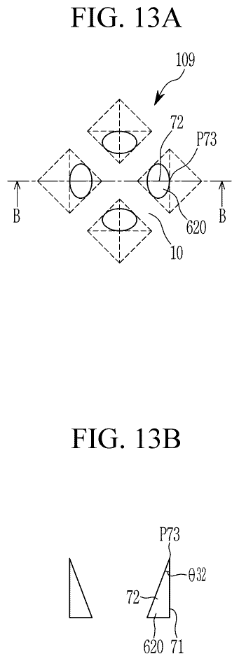

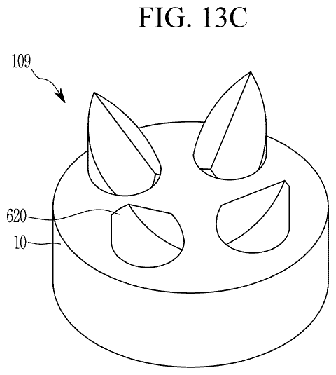

FIGS. 13A, 13B, and 13C are a top plan view, a cross-sectional view, and a perspective view of an inspection probe member according to a tenth embodiment of the present disclosure manufactured by the control method according to the second embodiment. With reference to FIGS. 13A, 13B, and 13C, in an inspection probe member 109 of the tenth embodiment, a contact protrusion 620 has a circular or elliptical shape in a plan view, the vertical portion 71 is formed as an outer curved surface of a circular or elliptical column, and the inclined portions 72 are formed as two inclined surfaces formed inside two opposite sides based on a center cutting line of a circle or ellipse. A vertex P73 of the contact protrusion 620 is formed at an upper end intersection point between the outer curved surface and the two inclined surfaces.

In the tenth embodiment, the contact protrusion 620 is formed so that the circular or elliptical column occupies only a part of an inner side of a planar quadrangular area of the contact protrusion 620 of the ninth embodiment. Therefore, the tenth embodiment may be applied to a smaller, preciser inspection target.

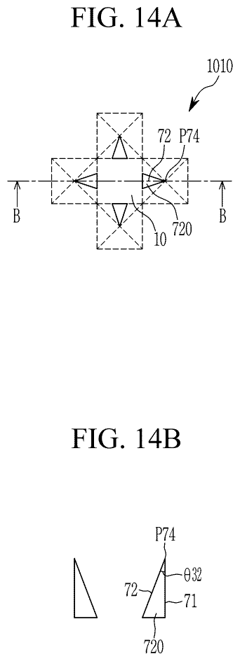

FIGS. 14A and 14B are a top plan view and a cross-sectional view of an inspection probe member according to an eleventh embodiment of the present disclosure manufactured by the control method of the second embodiment. With reference to FIGS. 14A and 14B, in an inspection probe member 1010 of the eleventh embodiment, a contact protrusion 720 has a triangular or isosceles triangular shape in a plan view in which a central angle is positioned outward, the vertical portion 71 is formed as an outer edge of a triangular column, and the inclined portion 72 is formed as a single inclined surface formed inward based on a center cutting line of the triangular column. A vertex P74 of the contact protrusion 720 is formed at an upper end intersection point between the outer edge and the single inclined surface.

In the eleventh embodiment, the contact protrusion 720 is formed so that the triangular or isosceles triangular column occupies only an inner portion of ¼ of a planar quadrangular area of the contact protrusion 520 of the eighth embodiment. Therefore, the eleventh embodiment may be applied to a smaller, preciser inspection target.

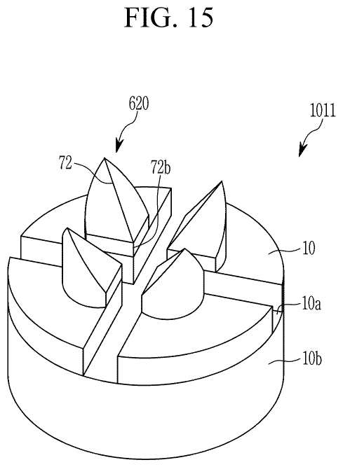

FIG. 15 is a perspective view of an inspection probe member according to a twelfth embodiment of the present disclosure manufactured by the control method according to the second embodiment. With reference to FIG. 15, in an inspection probe member 1011 of the twelfth embodiment, the body part 10 further includes an extension body 10b divided into grooves 10a so as to correspond to the plurality of contact protrusions 620. The contact protrusion 620 further includes an extension protrusion 72b extending perpendicularly to the extension body 10b from a lowermost end of the inclined portion 72.

The extension protrusion 72b, which is further provided on the contact protrusion 620, and the groove 10a, which is further formed in the body part 10, in the twelfth embodiment make it possible to inspect the inspection target even in a case in which the contact protrusion 620 is more deeply inserted into the inspection target, in comparison with the contact protrusion 520 and the body part 10 in the tenth embodiment in which the extension protrusion 72b and the groove 10a are not provided.

While the exemplary embodiments of the present disclosure have been described above, the present disclosure is not limited thereto, and various modifications can be made and carried out within the scope of the claims, the detailed description of the present disclosure, and the accompanying drawings, and also fall within the scope of the present disclosure.

(Description of Symbols)

| | |
|---|---|
| 10: Body part | 10a: Groove |
| 10b: Extension body | 20: Contact protrusion |
| 21, 71: Vertical portion | 22, 72: Inclined portion |
| 30: Substrate | 31: Pyramidal groove |
| 41: First layer | 42: Second layer |
| 100: Inspection probe member | 101: Inspection probe member |
| 102: Inspection probe member | 103: Inspection probe member |
| 104: Inspection probe member | 105: Inspection probe member |
| 106: Inspection probe member | 107: Inspection probe member |
| 108: Inspection probe member | 109: Inspection probe member |
| 1010: Inspection probe member | 1011: Inspection probe member |
| 200: Inspection probe member | 201: Contact protrusion |
| 202: Contact protrusion | 203: Contact protrusion |
| 204: Contact protrusion | 205: Contact protrusion |
| 210: Body part | 220: Contact protrusion |
| 230: First metal layer | 300: Inspection probe member |
| 320, 420, 520, 620 720: Contact protrusion | 342: Second layer |
| 411: First pattern | 421: Second pattern |
| 3411: First pattern | 3421: Second pattern |
| A1: Corresponding region | H: Height difference |
| H2: Height difference | L1, L31: Vertical distance |
| L2, L32: Vertical distance | P1: Vertex |
| P7: Vertex | P11: Vertex |
| P12: Vertex | P13: Vertex |
| P14: Vertex | P15: Vertex |
| P71: Vertex | P72: Vertex |
| P73: Vertex | P74: Vertex |
| θ1: First angle | θ2: Second angle |
| θ32: Second angle | |

1. A method of manufacturing an inspection probe member, which manufactures an inspection probe member having a plurality of contact protrusions provided on a body part, the method comprising:
a first step of forming a plurality of pyramidal grooves in a region corresponding to the body part of a substrate based on a direction perpendicular to a surface of the substrate;
a second step of filling the pyramidal groove with a photoresist and coating the surface of the substrate with the photoresist as a first layer;
a third step of patterning the first layer in a first pattern so as to correspond to the contact protrusion and the body part;
a fourth step of filling a space of the pyramidal groove, which corresponds to the contact protrusion, with a photoresist and coating the first pattern with the photoresist as a second layer;
a fifth step of patterning the second layer in a second pattern so as to correspond to the contact protrusion and the body part;
a sixth step of forming the contact protrusion and the body part by plating an internal space, which is set by the pyramidal groove, the first pattern, and the second pattern, with metal; and
a seventh step of acquiring the inspection probe member by removing the first pattern, the second pattern, and the substrate.

2. The method of claim 1, wherein:
in the third step, a part of a first angle θ1 of the pyramidal groove is opened by the first pattern, and a second angle θ2 of a vertex of the contact protrusion to be manufactured is a part of the first angle (θ2=(part*θ1).

3. The method of claim 2, wherein:
in the third step, the first pattern defines an inner vertical portion, and the pyramidal groove defines an outer inclined portion, such that the vertex is formed.

4. The method of claim 3, wherein:
in the fifth step, the first pattern is opened by the second pattern, and the plurality of contact protrusions having the vertices is formed on the body part to be manufactured.

5. The method of claim 4, wherein:
in the fifth step, a height difference H is formed between a surface of the first pattern at an inner upper end of the pyramidal groove and a surface of the substrate at an outer upper end of the pyramidal groove by the first pattern.

6. The method of claim 5, wherein:
in the sixth step, the height difference H is formed between a surface of the body part vertically connected to an inner side of the vertex of the contact protrusion and a surface of the body part inclinedly connected to an outer side of the contact protrusion vertex by the first pattern.

7. The method of claim 1, wherein:
the sixth step comprises:
a sixth-first step of forming a first metal layer by plating an inner surface of the internal space, which is set by the pyramidal groove, the first pattern, and the second pattern, with first metal; and
a sixth-second step of completing the contact protrusion and the body part as a second metal layer by plating the first metal layer with second metal.

8. The method of claim 7, wherein:
in the seventh step, the inspection probe member, in which the contact protrusion and the body part have the first metal layer and the second metal layer, is acquired by removing the first pattern, the second pattern, and the substrate.

9. The method of claim 2, wherein:
in the third step, the first pattern defines an outer vertical portion, and the pyramidal groove defines an inner inclined portion, such that the vertex is formed.

10. The method of claim 9, wherein:
in the fifth step, the first pattern is opened by the second pattern, and the plurality of contact protrusions having the vertices is formed on the body part to be manufactured.

11. The method of claim 10, wherein:
in the fifth step, a height difference H2 is formed between a surface of the first pattern at an outer upper end of the pyramidal groove and a surface of the substrate at an inner upper end of the pyramidal groove by the first pattern.

12. The method of claim 11, wherein:
in the sixth step, a height difference H is formed between a surface of the body part inclinedly connected to an inner side of the contact protrusion vertex and a surface of the body part vertically connected to an outer side of the contact protrusion vertex by the first pattern.

13. An inspection probe member comprising:
a body part having a column shape; and
a plurality of contact protrusions have vertices and provided on the body part set in a column cross-section region,
wherein the contact protrusion comprises:
a vertical portion formed to be perpendicular to a surface of the body part and connected to the vertex; and
an inclined portion inclinedly connected to an upper end of the vertical portion on the surface of the body part and connected to the vertex.

14. The inspection probe member of claim 13, wherein:
the body part is formed in a cylindrical shape, and
the contact protrusion has the vertical portion provided at a center side in a circular region, and the inclined portion provided outside the vertical portion in the circular region.

15. The inspection probe member of claim 14, wherein:
the contact protrusion has an arc fan shape in a plan view,
the vertical portion is formed as an inner edge of an arc column,
the inclined portions are formed as two inclined surfaces formed outside two opposite sides based on a center cutting line of the arc column, and
the vertex is formed at an upper end intersection point between the inner edge and the two inclined surfaces.

16. The inspection probe member of claim 14, wherein:
the contact protrusion has an isosceles triangular shape in a plan view in which a central angle is positioned outward,
the vertical portion is formed as an inner side surface of a triangular column,
the inclined portions are formed as two inclined surfaces formed outside two opposite sides based on a center cutting line of the triangular column, and
the vertex is formed at an upper end intersection point between the inner side surface and the two inclined surfaces.

17. The inspection probe member of claim 14, wherein:
the contact protrusion has a quadrangular shape in a plan view,
the vertical portion is formed as an inner edge of a quadrangular column,
the inclined portions are formed as two inclined surfaces formed outside two opposite sides based on a diagonal center cutting line of the quadrangular column, and
the vertex is formed at an upper end intersection point between the inner edge and the two inclined surfaces.

18. The inspection probe member of claim 14, wherein:
the contact protrusion has a circular or elliptical shape in a plan view,
the vertical portion is formed as an inner curved surface of a circular or elliptical column,
the inclined portions are formed as two inclined surfaces formed outside two opposite sides based on a center cutting line of a circle or ellipse, and
the vertex is formed at an upper end intersection point between the inner curved surface and the two inclined surfaces.

19. The inspection probe member of claim 14, wherein:
the contact protrusion has a triangular shape in a plan view,
the vertical portion is formed as an inner edge of a triangular column,
the inclined portion is formed as a single inclined surface formed outward based on a center cutting line of a triangle, and
the vertex is formed at an upper end intersection point between the inner edge and the single inclined surface.

20. The inspection probe member of claim 14, wherein:
the contact protrusion has a circular or elliptical shape in a plan view,
the vertical portion is formed as an inner curved surface of a circular or elliptical column,
the inclined portion is formed as a single inclined surface formed outward based on a center cutting line of a circle or ellipse, and
the vertex is formed at an upper end intersection point between the inner curved surface and the single inclined surface.

21. The inspection probe member of claim 13, wherein:
the contact protrusion has the vertical portion provided outside the column cross-section region, and the inclined portion provided inside the vertical portion in the column cross-section region.

22. The inspection probe member of claim 21, wherein:
the contact protrusion has an arc fan shape in a plan view,
the vertical portion is formed as an outer edge of an arc column,
the inclined portions are formed as two inclined surfaces formed inside two opposite sides based on a center cutting line of the arc column, and
the vertex is formed at an upper end intersection point between the outer edge and the two inclined surfaces.

23. The inspection probe member of claim 21, wherein:
the contact protrusion has a triangular shape in a plan view in which a central angle is positioned inward,
the vertical portion is formed as an outer side surface of a triangular column,
the inclined portions are formed as two inclined surfaces formed inside two opposite sides based on a center cutting line of the triangular column, and
the vertex is formed at an upper end intersection point between the outer side surface and the two inclined surfaces.

24. The inspection probe member of claim 21, wherein:
the contact protrusion has a quadrangular shape in a plan view,
the vertical portion is formed as an outer edge of a quadrangular column,
the inclined portions are formed as two inclined surfaces formed inside two opposite sides based on a diagonal center cutting line of the quadrangular column, and
the vertex is formed at an upper end intersection point between the outer edge and the two inclined surfaces.

25. The inspection probe member of claim 21, wherein:
the contact protrusion has a circular or elliptical shape in a plan view,
the vertical portion is formed as an outer curved surface of a circular or elliptical column,
the inclined portions are formed as two inclined surfaces formed inside two opposite sides based on a center cutting line of a circle or ellipse, and
the vertex is formed at an upper end intersection point between the outer curved surface and the two inclined surfaces.

26. The inspection probe member of claim 21, wherein:
the contact protrusion is a triangular shape in a plan view in which a central angle is positioned outward,
the vertical portion is formed as an outer edge of a triangular column,
the inclined portion is formed as a single inclined surface formed inward based on a center cutting line of the triangular column, and
the vertex is formed at an upper end intersection point between the outer edge and the single inclined surface.

27. The inspection probe member of claim 13, wherein:
the body part further comprises an extension body divided into grooves so as to correspond to the plurality of contact protrusions, and
the contact protrusion further comprises an extension protrusion extending perpendicularly to the extension body from a lowermost end of the inclined portion.
